(19) United States
(12) Patent Application Publication
(10) Pub. No.: US 2026/0178792 A1
(43) Pub. Date: Jun. 25, 2026

(54) SYSTEMS AND METHODS FOR AUTOMATED ROUTING-DESIGN GENERATION

(71) Applicant: Toyota Motor Engineering & Manufacturing North America, Inc., Plano, TX (US)

(72) Inventors: Danny J. Lohan, West Bloomfield, MI (US); Stav Ashur, Urbana, IL (US); Isaac Burton Love, Champaign, IL (US); Billy J. Davis, Ypsilanti, MI (US); Ercan Mehmet Dede, Ann Arbor, MI (US); Paul Donald Schmalenberg, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/999,543

(22) Filed: Dec. 23, 2024

(51) Int. Cl. G06F 30/18

(52) U.S. Cl. CPC G06F 30/18

(57) ABSTRACT

Systems and methods described herein relate to automatically generating routing designs. In one embodiment, a system simplifies the geometry of a computerized representation of a target system in which one or more of electrical wires, optical cables, pipes, and hoses are to be routed from a first set of connection points to a second set of connection points. The system also identifies automatically candidate route paths between the first and second sets of connection points. The system also generates automatically, based on the candidate route paths, alternative route sets in accordance with one or more constraints. The system also clusters automatically the alternative route sets into groups based, at least in part, on a multi-factor similarity metric that is a sum of weighted single-factor distance, interference, and composition similarity metrics. A particular route set selected from among the alternative route sets in the groups is implemented in the target system.

### TECHNICAL FIELD

The subject matter described herein relates in general to target systems that include one or more of electrical wires, optical cables, pipes, and hoses and, more specifically, to systems and methods for the automated generation of routing designs for such target systems.

### BACKGROUND

Designing systems as diverse as vehicles, vehicular fuel-cell systems, vehicular hydraulic systems, power plants, oil refineries, aircraft engines, and computing systems involves routing one or more of electrical wires, optical cables, pipes, and hoses between sets of connection points. In some cases, this routing-design problem is quite complex due to the number of connection points and electrical wires, optical cables, pipes, and/or hoses involved. Engineering teams manually creating a routing design can end up spending many hours on this time-consuming and often-iterative task to achieve a suboptimal configuration.

A variety of software tools and algorithms have been developed to automatically generate minimum-length routing designs. Though such tools can be helpful in some applications, they are not comprehensive enough for use in creating complete routing designs for complex target systems such as vehicles. Also, current design methods, whether software-based or manual engineering workflows, typically consider one pipe, wire, etc., at a time.

### SUMMARY

Embodiments of a system for automatically generating routing designs are presented herein. In one embodiment, the system comprises a processor and a memory storing machine-readable instructions that, when executed by the processor, cause the processor to simplify the geometry of a computerized representation of a target system in which one or more of electrical wires, optical cables, pipes, and hoses are to be routed from a first set of connection points to a second set of connection points. The memory also stores machine-readable instructions that, when executed by the processor, cause the processor to identify automatically candidate route paths between the first and second sets of connection points. The memory also stores machine-readable instructions that, when executed by the processor, cause the processor to generate automatically, based on the candidate route paths, alternative route sets in accordance with one or more constraints. The memory also stores machine-readable instructions that, when executed by the processor, cause the processor to cluster automatically the alternative route sets into groups based, at least in part, on a multi-factor similarity metric that is a sum of weighted single-factor distance, interference, and composition similarity metrics. A particular route set selected from among the alternative route sets in the groups is implemented in the target system.

Another embodiment is a non-transitory computer-readable medium for automatically generating routing designs and storing instructions that, when executed by a processor, cause the processor to simplify the geometry of a computerized representation of a target system in which one or more of electrical wires, optical cables, pipes, and hoses are to be routed from a first set of connection points to a second set of connection points. The instructions also cause the processor to identify automatically candidate route paths between the first and second sets of connection points. The instructions also cause the processor to generate automatically, based on the candidate route paths, alternative route sets in accordance with one or more constraints. The instructions also cause the processor to cluster automatically the alternative route sets into groups based, at least in part, on a multi-factor similarity metric that is a sum of weighted single-factor distance, interference, and composition similarity metrics. A particular route set selected from among the alternative route sets in the groups is implemented in the target system.

Another embodiment is a method of automatically generating routing designs, the method comprising simplifying the geometry of a computerized representation of a target system in which one or more of electrical wires, optical cables, pipes, and hoses are to be routed from a first set of connection points to a second set of connection points. The method also includes identifying automatically candidate route paths between the first and second sets of connection points. The method also includes generating automatically, based on the candidate route paths, alternative route sets in accordance with one or more constraints. The method also includes clustering automatically the alternative route sets into groups based, at least in part, on a multi-factor similarity metric that is a sum of weighted single-factor distance, interference, and composition similarity metrics. A particular route set selected from among the alternative route sets in the groups is implemented in the target system.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 is a process-flow diagram of an automated routing-design generation system, in accordance with an illustrative embodiment of the invention.

FIG. 2 illustrates a target system for which a routing design is to be generated by an automated routing-design generation system, in accordance with an illustrative embodiment of the invention.

FIGS. 3A-3C illustrate techniques applied in automatically generating alternative route sets, in accordance with an illustrative embodiment of the invention.

FIGS. 4A-4C illustrate single-factor similarity metrics, in accordance with an illustrative embodiment of the invention.

FIG. 5 illustrates examples of the application of three single-factor similarity metrics to alternative route sets, in accordance with an illustrative embodiment of the invention.

FIG. 6 illustrates examples of employing randomness in generating alternative route sets to increase variety among the alternative route sets, in accordance with an illustrative embodiment of the invention.

FIG. 7 is a block diagram of an automated routing-design generation system, in accordance with an illustrative embodiment of the invention.

FIG. 8 is a flowchart of a method of automatically generating routing designs for a target system, in accordance with an illustrative embodiment of the invention.

To facilitate understanding, identical reference numerals have been used, wherever possible, to designate identical elements that are common to the figures. Additionally, elements of one or more embodiments may be advantageously adapted for utilization in other embodiments described herein.

### DETAILED DESCRIPTION

Various embodiments of systems and methods for automated routing-design generation described herein overcome the weaknesses of prior-art software tools. For example, conventional software workflows may generate new solutions by adjusting the routing order or changing the weight of the objective function to create a Pareto curve. These designs are typically evaluated in the context of the Pareto curve to down-select a best design. One challenge with such a framework is that the Pareto designs are often self-similar (i.e., insufficiently diverse), and the simple design objectives employed in such platforms often overlook practical engineering complexities. To address these problems, the various embodiments discussed herein employ novel strategies to selectively and in a controlled manner increase route complexity and diversity during generation to create more cost-competitive alternatives from which a final selection of a routing design can be made. One aspect of those strategies is a novel set of metrics to measure the similarity between different route sets. In electrical-wiring applications, the similarity metrics can address complexities such as wire harnesses, in which groups of wires are bundled and secured together.

The various embodiments automate the generation of routing designs in a process that includes (1) simplifying the geometry of a computerized representation of a target system in which one or more electrical wires, optical cables, pipes, and hoses are to be routed from a first set of connection points to a second set of connection points; (2) automatically identifying candidate route paths between the first and second sets of connection points; (3) automatically generating, based on the candidate route paths, alternative route sets in accordance with one or more constraints; and (4) automatically clustering the alternative route sets into groups based, at least in part, on a multi-factor similarity metric that is the sum of weighted single-factor distance, interference, and composition similarity metrics.

In some embodiments, the system automatically selects one representative route set from each group prior to final selection of a routing design. Regardless of whether the alternative route sets are first reduced in number in that fashion, a particular route set is ultimately selected from among the generated alternative route sets, and that particular route set is implemented (built out) in the target system. In some embodiments, one or more design engineers make the final selection of the particular route set to be implemented in the target system.

Herein, a “target system” is any system in which one or more of electrical wires, optical cables, pipes, and hoses are to be routed from a first set of connection points to a second set of connection points. The target system can be any of a variety of such systems, including, without limitation, vehicles (e.g., internal-combustion-engine vehicles, electric vehicles, hybrid vehicles, etc.), vehicular fuel-cell systems, vehicular hydraulic systems, power plants, oil refineries, aircraft engines, and computing systems (e.g., servers, desktop computers, laptop computers, etc.). Though this description presents examples involving the routing of electrical wires in a target system, the principles and techniques discussed are equally applicable, sometimes with modification or adaptation, to routing designs for optical cables, pipes, hoses, etc.

The “pipes” and “hoses” referred to herein can carry a variety of liquids and gases. For example, liquids include, without limitation, coolant, water, oil, gasoline or other types of fuels/propellants, and gases include, without limitation, natural gas, oxygen, and hydrogen.

A “route path” is a path (trajectory in three-dimensional space) within a target system via which a particular electrical wire (or wire harness), optical cable (or bundle of optical cables), pipe, or hose connects one or more start or origination connection points with one or more corresponding terminal connection points. A “route set” is one realization of a complete routing design that connects all defined origination connection points with all defined terminal connection points. Since the various embodiments described herein generate multiple distinct route sets, the various possible route sets generated are referred to as “alternative route sets,” one of which is ultimately selected for implementation (building out) in the target system.

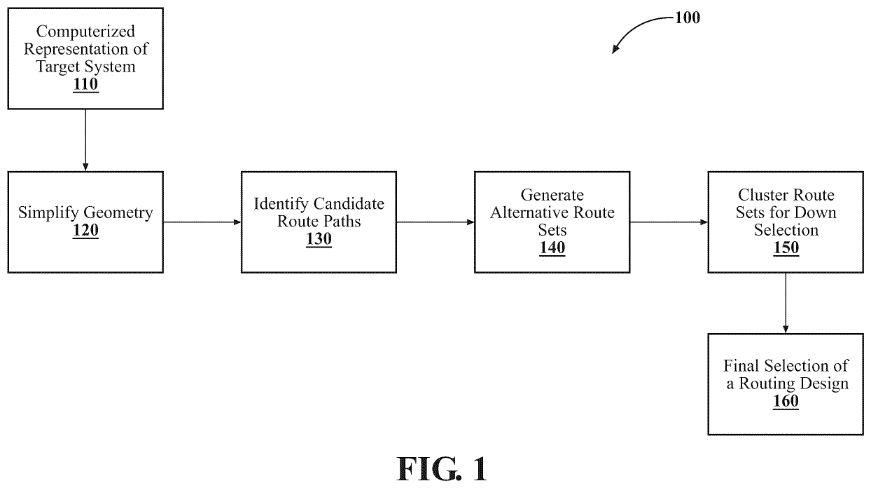

FIG. 1 is a process-flow diagram of an automated routing-design generation system, in accordance with an illustrative embodiment of the invention. Process flow 100 begins with a computerized representation 110 of a target system. For example, computerized representation 110 can be the product of a computer-aided engineering (CAE) platform. In some embodiments, computerized representation 110 includes stereolithography (STL) files exported from a CAE tool such as CATIA (an acronym for “Computer-Aided Three-Dimensional Interactive Application”) and associated metadata such as connection information, design constraints, etc. Such metadata can be stored in, for example, one or more spreadsheets. In these embodiments of an automated routing-design generation system, the system imports the STL files and associated metadata prior to simplifying the geometry of the computerized representation 110 (block 120).

The various embodiments of an automated routing-design generation system 700 described herein employ numerical methods. CAE representations of a target system such as STL files contain many tessellations (tiny triangular-shaped elements) that make up the digital rendering. In that form, the calculations involved in generating route sets becomes burdensome. Consequently, the system, at block 120, simplifies the geometry of the computerized representation 110 by reducing the number of tessellations that represent a given surface of the target system. This speeds up the calculations performed by the automated routing-design generation system. In some embodiments, the system simplifies the geometry of computerized representation 110 automatically.

At this early stage of simplifying geometry (block 120), the system also reviews the connections for the target system. This involves scrutinizing and verifying which start or origination connection points are to be connected with which terminal connection points in the target system.

As mentioned above, part of the computerized representation 110 is metadata, including various design constraints. At the geometry-simplification stage, clearance requirements relative to components of the target system are applied and satisfied. In some embodiments, over 200 individual design constraints are grouped under the following seven categories: (1) “Slack,” which refers to how much slack the system leaves in wires/pipes/hoses so that when they vibrate, a connector does not become unplugged; (2) “Bend Radius,” which refers to how smooth the wire/pipe/hose bends are; (3) “Harness or Independent Wire,” which refers to how a wire harness is bundled and branched; (4) “Clearance,” which refers to how far wires/pipes/hoses must be from one another due to, e.g., factors such as heat or electromagnetic interference; (5) “Insulation,” which refers to the clearance relative to a part that requires a specified amount of insulation for protection against, e.g., high voltage or heat; (6) “Clamping Distance,” which refers to the intervals at which wires/pipes/hoses should be clamped along a route path to prevent them from “floating in mid-air”; and (7) “Isolation,” which refers to certain wires/pipes/hoses being kept separate from one another (e.g., high- and low-voltage wires may have electromagnetic interference if they are too close to one another), forcing such wires to be routed through different areas.

At block 130, the system automatically identifies candidate route paths between the origination and terminal connection points of the target system. In some embodiments, this involves defining many discrete points of a routing mesh in the three-dimensional (3D) air volume of the target system between the components of the target system. The system then determines the feasible (physically possible) route paths in the routing mesh. In some embodiments, each edge (line connecting two mesh points) is assigned a weight based on its length. If a route path lies too close to a sensitive component (e.g., a very hot component), a penalty is assigned to that route, requiring that more expensive wire (e.g., better-insulated wire) be used for that route path. As those skilled in the art will recognize, this presents a tradeoff between adding more length to the wire to avoid getting too close to a sensitive component and accepting the penalty and using the more expensive wire with better insulation to pass more closely to the sensitive component.

At block 140, the system automatically generates, based on the identified candidate route paths, multiple alternative route sets that satisfy one or more specified constraints. The number of route sets the system generates varies, depending on the embodiment and input settings/preferences of a user. For example, in one embodiment, the system might generate tens of route sets; in another embodiment, hundreds.

At this stage of process flow 100, a user of the automated routing-design generation system can adjust certain route-dependent constraints. For example, the system can include a user interface element (e.g., a virtual slider) that permits the user to select the “complexity” of the generated route sets. At one extreme, the system produces route sets including the simplest possible route paths. At the other extreme, the system produces route sets including route paths that are elaborate and roundabout. A user can adjust the complexity to be somewhere between those two extremes. Choosing a setting somewhere between the two extremes helps to ensure that a diversity of designs (alternative route sets) is produced. The “harness settings” constraint limits the maximum distance between connectors that lead to a single branch point. Though this particular constraint applies to electrical wires or optical cables, there are analogous considerations for pipes, hoses, etc. The “branch settings” constraint (1) limits the maximum number of wires that can diverge at a given branch point and (2) limits the minimum length of wire from connector to branch point for assembly considerations.

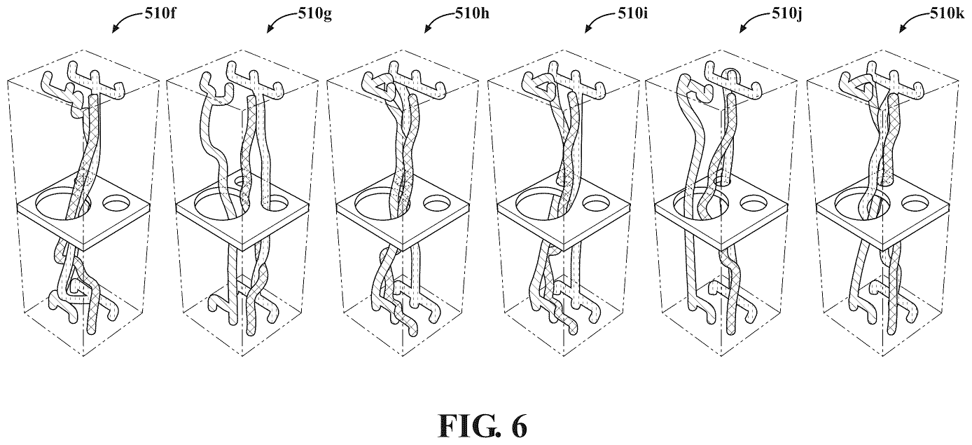

At the stage of generating the alternative route sets, the technique of randomly assigning some of the wires to harnesses helps to increase the variety of the routing designs the system produces. This is discussed further below in connection with FIG. 6. In some embodiments, the route paths of a route set are represented as splines. As those skilled in the art are aware, a spline, in mathematical terms, is a function defined in piecewise fashion by polynomials.

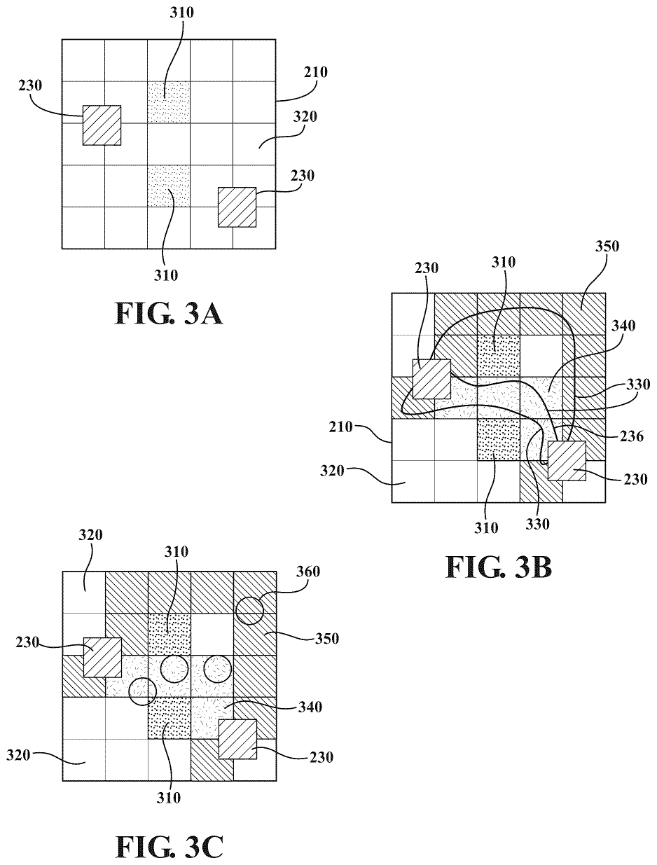

Further techniques applied during the generation of the alternative route sets are discussed in detail below, and some of those techniques and concepts are illustrated in FIGS. 3A-3C.

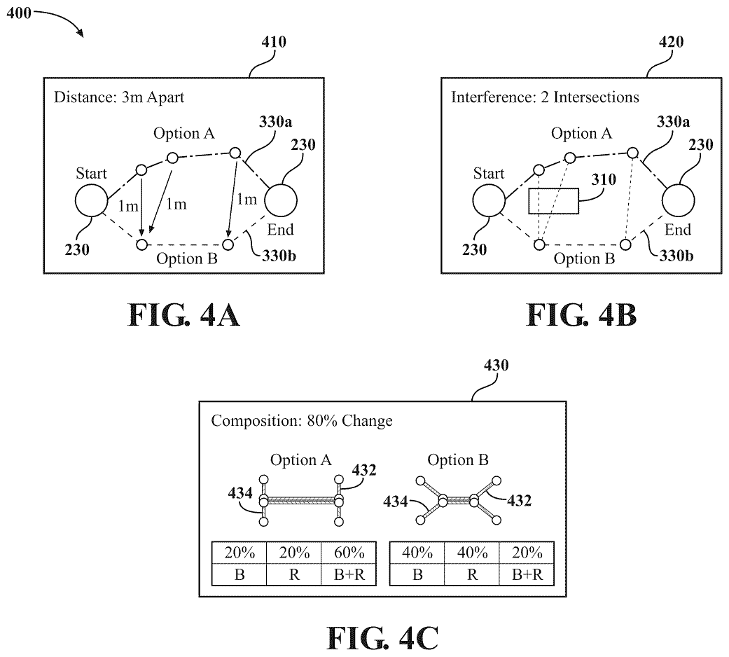

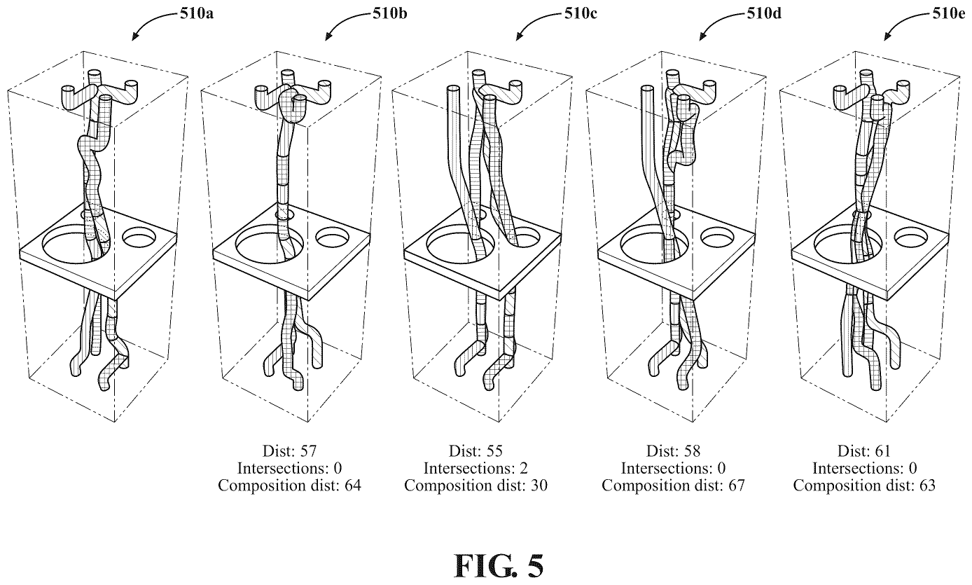

At block 150, the system automatically clusters the alternative route sets into groups based, at least in part, on a multi-factor similarity metric that is the sum of weighted single-factor distance, interference, and composition similarity metrics. This phase of process flow 100, including the multi-factor and single-factor similarity metrics, is discussed in greater detail below in connection with FIGS. 4A-4C and 5.

At block 160, a final selection of a routing design for the target system is made, as discussed above. As also discussed above, the final routing design is then implemented (built out) in the target system. That is, physical electrical wiring, optical cables, pipes, and/or hoses are installed in the target system between the origination and terminal connection points in accordance with the final routing design. In some embodiments, this final selection of a particular routing design for implementation is made by a human engineer.

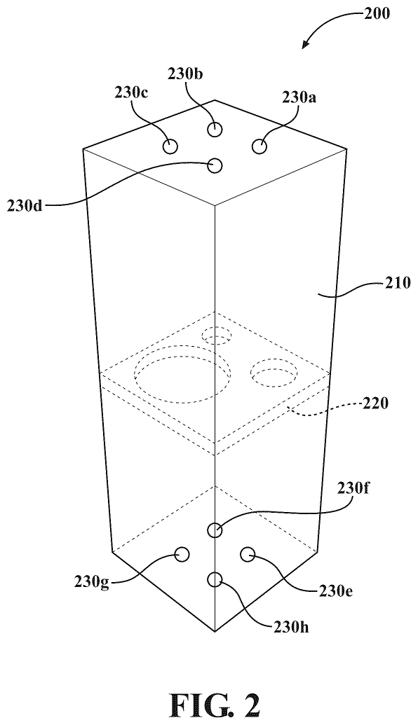

FIG. 2 illustrates a target system 200 for which a routing design is to be generated by an automated routing-design generation system, in accordance with an illustrative embodiment of the invention. As shown in FIG. 2, the computerized representation 110 of the target system 200 includes an air volume 210 and various kinds of routing hardware 220 (in this simple example, a plate that includes three holes of differing diameters). As also shown in FIG. 2, target system 200 includes connection points 230. In this simplified example, there are four origination connection points, 230a-d and four terminal connection points 230e-g, respectively. That is, connection point 230a connects with connection point 230e, connection point 230b connects with connection point 230f, connection point 230c connects with connection point 230g, and connection point 230d connects with connection point 230h. As discussed above in connection with FIG. 1, at block 130 of process flow 100, the system defines a mesh grid in the air volume 210 in preparation for identifying candidate route paths between the connection points.

Block 140 of process flow 100, generating the alternative route sets, will next be described in greater detail. At a high level, the automated routing-design generation system (1) decomposes the air volume 210 between components of the target system 200 into a plurality of regions and computes a heuristic that yields a probability distribution over the plurality of regions, (2) identifies high-density regions among the plurality of regions, and (3) places waypoints in prioritized regions among the plurality of regions to control the complexity of the alternative route sets.

Central to many of the algorithms discussed below is the ability to compute the shortest path between two vertices. In an undirected graph with weighted edges, this can be done quickly and efficiently with polynomial-time complexity using algorithms such as A* or Dijkstra's algorithm. However, where there are more than two points to be connected minimally, a different approach is employed.

Let G=(V, E, w(·)) be an undirected and connected graph with vertices V, edges E, and non-negative edge weights w(·): E→ [symbol] _{≥0}. Let S⊆V be a subset of the vertices of G. The minimum Steiner tree problem on the graph G is to find the least cost tree T⊆V such that S⊆T; i.e., to find the minimum tree T such that the vertices of S are contained in the tree T. In general, this problem is NP-hard. However, in the special case that S=V, the problem is exactly finding the minimum spanning tree of G, which can be done efficiently in polynomial time. This insight led to the creation of Kou's minimum Steiner tree approximation algorithm, Algorithm 1, which executes in polynomial time with a time complexity of O(|S∥V|²). Kou's algorithm has the added benefit of bounding the error of the solution by

$$2 ( 1 - \frac{1}{l} ) ,$$

where l is the number of leaves in the benefit of bounding the error of the solution by optimal tree.

Algorithm 1 Kou's algorithm

Input: Graph G = (V, E, w(·)), vertices to connect S.
Output: Tree T such that T ∩ S = S.
1: Gₘ ← MetricClosureSubgraph(G, S)
2: Tₘ ← MinimalSpanningTree(Gₘ)
3: Gₛ ← PathReplace(Tₘ, G)
4: Tₛ ← MinimalSpanningTree(Gₛ)
5: T ← Prune(Tₛ, S)
6: return T

In Algorithm 1, MetricClosureSubgraph(G, S) constructs the subgraph induced by vertices S of the metric closure of G. The PathReplace(G₁, G₂) subroutine replaces each edge (u, v) in G₁ with a shortest path from G₂ connecting u and v. The Prune(·) subroutine is outlined in Algorithm 2 and serves to recursively remove any leaves from the tree that are not elements of S.

Algorithm 2 Prune

| Input: Tree T = (V, E, w(·)), required vertices S. | |
|---|---|
| Output: Tree T with leaves not in S pruned. | |
| 1: | Create empty leaf queue Q |
| 2: | for all v ∈ V do |
| 3: | if v is a leaf and v ∉ S then |
| 4: | Q.push(v) |
| 5: | end if |
| 6: | end for |
| 7: | while Q is not empty do |
| 8: | v ← Q.next( ) |
| 9: | u ← neighbor(v) |
| 10: | Remove v from T |
| 11: | if u is a leaf and u ∉ S then |
| 12: | Q.push(u) |
| 13: | end if |
| 14: | end while |
| 15: | return T |

An adaptation of the minimum Steiner tree problem is used in connection with the steering heuristic discussed further below. Herein, this adaptation is called a “minimum Steiner tree with option sets.” Instead of requiring a specific vertex to be included in the tree, it is required that at least one vertex from a set of vertices be included. This is referred to herein as an “option set.” The problem is generalized to allow for as many option sets as needed. Formally, let Sᵢ⊆V for i∈{1, 2, . . . , N}, T∩Sᵢ≠Ø. This problem can easily be proved to be NP-hard, as it can immediately be used to solve the minimum Steiner tree problem by choosing option sets with exactly one element. A modified version of Kou's algorithm can be used to find approximate solutions to the minimum Steiner tree problem with option sets. The key differences from Kou's original algorithm are that the trimming step is modified to account for the option sets, and the trimming step is applied twice instead of once. Algorithm 3 gives the new algorithm for approximating the minimum Steiner tree problem with option sets. The modified trimming step is outlined in Algorithm 4. The options-trimming step functions in a manner similar to Kou's version but instead uses a priority queue so that non-central leaves are pruned first. The modified trimming step also performs checking to ensure that the last vertex in a given option set is not pruned. The centrality of the vertex is used to calculate the priority for the queue, with the greatest priority item being used first.

Algorithm 3 Option sets algorithm
Input: Graph G = (V, E, w(·)), option sets Sᵢ, i ∈ {1, 2, ... , N}.
Output: Tree T such that ∀i, T ∩ Sᵢ # ∅.
1: Gₘ ← MetricClosureSubgraph(G, ∪_{i∈(1,2,...,N}} Sᵢ)
2: Tₘ ← MinimalSpanningTree(Gₘ)
3: ${T}_{m} ← OptionSetsPrune ( {T}_{m} , {\{ {S}_{i} \}}_{i}^{N} )$
4: Gₛ ← PathReplace(Tₘ, G)
5: Tₛ ← MinimalSpanning Tree(Gₛ)
6: $T ← OptionSetsPrune ( {T}_{s} , {\{ {S}_{i} \}}_{i}^{N} )$
7: return T

Algorithm 4 OptionSetsPrune

```
Input: Tree T = (V, E, w(·)), option sets Sᵢ, i ∈ {1, 2, ... , N}.
Output: Tree T with at least one vertex of each Sᵢ and other leaves
heuristically pruned.
  1: Create empty priority leaf queue Q
  2: Create empty hashmap M
  3: for all v ∈ V do
  4: M[v] ← DistanceToCenter(T, v)
  5: if v is a leaf then
  6: Q.push (v, M[v])
  7: end if
  8: end for
  9: while Q is not empty do
10: v ← Q.next( )
11:  $if NotLastOption ( v , {\{ {S}_{i} \}}_{i}^{N} ) then$
12:  $RemoveFromOptionSets ( v , {\{ {S}_{i} \}}_{i}^{N} )$
13: u ← neighbor(v)
14: Remove v from T
15: if u is a leaf then
16: Q.push (u, M [u])
17: end if
18: end if
19: end while
20: return T
```

The first loop of the OptionSetsPrune algorithm creates a priority queue for the current leaves of the tree. The queue is ordered by the distance of each leaf to the center of the tree T and is computed in the subroutine DistanceToCenter(T, v). The subroutine NotLastOption

$$( v , {\{ {S}_{i} \}}_{i}^{N} )$$

returns “true” if v is the only element of any of the sets

$${\{ {S}_{i} \}}_{i}^{N}$$

and “false” otherwise. The subroutine RemoveFromOptionSets

$$( v , {\{ {S}_{i} \}}_{i}^{N} )$$

removes v from any sets it may be present in. Together, these routines work to ensure that the trimmed tree contains at least one vertex from each of the original option sets.

To generate a variety of different interconnect paths, it is important to understand the relationship between port vertices and the vertices along which a connecting path or tree would traverse. Having an understanding of which vertices in a large graph are important and “between” the port vertices and which vertices are unimportant and far away will lead to a useful sampling heuristic below.

In the analysis of graphs, centrality metrics are often used to understand similar properties in a variety of networks. Most relevant to the embodiments described herein is “betweenness centrality.” The betweenness centrality of a vertex is the number of pairwise shortest paths which that vertex participates in taken over all possible pairs in the graph. Formally, let G=(V, E, w(·)) be an undirected and connected graph with vertices V, edges E, and non-negative edge weights w(·): E→ [symbol] _{≥0}. Let σ_{pq} be the number of simple shortest paths from p to q for some p≠q∈V. Likewise, let σ_{pq}(v) be the number of simple shortest paths from p to q that also pass through v. The betweenness centrality C^{B}(v) of a vertex v is given as:

$${C}^{B} ( v ) = {\sum }_{p \neq v \neq q ∈ V} \frac{{σ}_{pq} ( v )}{{σ}_{pq}}$$

The betweenness centrality captures a notion of which vertices are “bottlenecks” through which a large number of shortest paths traverse. These vertices are important generally but not necessarily for a specific start and terminal pair p and q. The betweenness centrality is adapted herein to a new metric called “two-point centrality” that considers only paths between two specific vertices. This is used in conjunction with a steered two-point centrality heuristic.

For two vertices p and q and a third vertex w≠p, q called the steering vertex, the shortest steered path p→w→q is computed, which is the union of the simple shortest paths p to w and w to q.

The steered path concept is key to the two-point centrality heuristic. The idea is that vertices that are important “bottlenecks” to a particular p and q will appear in many steered paths over many different steering vertices. Let p and q be as before, and let w∈V, w≠p, q. Let σ_{pq}(·|w) be the number of shortest steered paths for p to w to q that also pass through v. The two-point centrality

$${C}_{pq}^{T} ( v )$$

of a vertex v is given as.

$${C}_{pq}^{T} ( v ) = {\sum }_{w , w \neq p , q , v} \frac{{σ}_{pq} ( v \vert w )}{{σ}_{pq} ( \cdot \vert w )}$$

The concept of two-point centrality can be generalized to k points by replacing the notion of steered shortest path connecting the vertices p to w to q with a steered minimum Steiner tree connecting the vertices of some set [symbol] and the steering point w. The two- and k-point centrality metrics can be further refined to consider only paths no longer than a given length. Formally, for the two-point centrality, let ϵ∈ [symbol] ⁺ be a positive number and let l be the length of the shortest path connecting p and q. Define σ^{ϵ}_{pq}(·|w) to be the number of shortest steered paths from p to w to q such that the total path length is less than (1+ϵ)l. Likewise, let σ_{pq}(v|w) be the number of shortest steered paths from p to w to q that also pass through v such that the total path length is less than (1+ϵ)l. The ϵ-two-point centrality is given as:

$${C}_{pq}^{T} ( v , ϵ ) = {\sum }_{w , w \neq p , q , v} \frac{{σ}_{pq}^{ϵ} ( v \vert w )}{{σ}_{pq}^{ϵ} ( \cdot \vert w )}$$

This concept is similarly extended to define the ϵ-k-point centrality where instead l is the size of the minimum Steiner tree connecting the k points. In practice, l is typically approximated due to the difficulty of computing the minimum Steiner tree.

In the case that bundles are not given, the wire bundles can be computed automatically. This is performed as an agglomerative clustering problem with a novel distance function. From a user perspective, agglomerative clustering provides a distinct advantage in requiring only one tunable parameter, the clustering cutoff, which can be readily adjusted without the need for expensive recomputing of clusters or the need to deduce the number of clusters.

To perform the clustering, each interconnect is considered to be a distinct object consisting of two port locations, and the clustering assigns each interconnect to a cluster. Agglomerative clustering uses a pairwise distance function measuring the distance between any two objects. In this case, this means that given two interconnects, each defined by two-port locations, a distance is computed. Intuitively, two interconnects should be part of the same bundle only if the two optimal paths for each interconnect are similar enough that costs are not increased too much by the bundling. To achieve this, the distance function should therefore be small if two interconnects have similar optimal paths and large otherwise. Additionally, it is desirable for interconnects in a bundle to have similar end points because this allows for nice hierarchical branching.

Let G=(V, E, w(·)) be a graph such that each vertex v E V corresponds to a point in [symbol] ³. Let I₁=(pₐ, p_{b}) and I₂=(qₐ, q_{b}) be interconnects, where pₐ, p_{b}, qₐ, and q_{b} are the ports. The pₐ, p_{b}, qₐ, and q_{b} are vertices in G and therefore correspond to a point in [symbol] ³ as well. Let Dₚₒᵣₜₛ(I₁, I₂): =min (∥pₐ−qₐ∥+∥p_{b}−q_{b}∥, ∥pₐ−q_{b}∥+∥p_{b}−qₐ∥). This yields the smallest sum of Euclidean distances between the ports of I₁ and the ports of I₂.

To heuristically measure how similar the optimal paths of two interconnects are, shortest paths in a graph are used. The idea is that, if two paths are similar, then if one path is held constant and the other path is recomputed but where edges shared with the fixed path are discounted, then the recomputed discounted path will be substantially cheaper than the original. This then leads to a ratio of the discounted path length divided by the original path length to normalize the result. Let l(u, v|G) give the length of the shortest path between two vertices u and v in G. Likewise, let P(u, v|G) give the actual path of the shortest path between two vertices u and v in G (one is chosen arbitrarily, if multiple exist) as a set of edges in E. For any e∈E, let

$$w ( e \vert u , v , G ) := \{ \begin{matrix}w ( e ) , & if e ∈ P ( u , v \vert G ) \\ 0 , & otherwise\end{matrix}$$

This defines a new weight function that is identical to the original except along those edges in the path P(u, v|G) where the new weight is 0. This weight function is used to compute the discounted path. Let G^{u,v}=(V, E, w(e|u, v, G)) be a new graph using the path discounted weight function. The distance using the ratio discussed above is then given as

$${D}_{path} ( {I}_{1} , {I}_{2} ) := min ( \frac{l ( ( {p}_{a} , {p}_{b} ) \vert {G}^{{q}_{a} , {q}_{b}} )}{l ( ( {p}_{a} , {p}_{b} ) \vert G )} , \frac{l ( ( {q}_{a} , {q}_{b} ) \vert {G}^{{p}_{a} , {p}_{b}} )}{l ( ( {q}_{a} , {q}_{b} ) \vert G )} ) ,$$

which yields the minimum of the two discounted differences. This then leads to the final distance function:

$$D ( {I}_{1} , {I}_{2} ) := {D}_{ports} ( {I}_{1} , {I}_{2} ) \cdot {D}_{path} ( {I}_{1} , {I}_{2} ) .$$

The compute the agglomerative clustering, first all pairwise distances are computed to populate the distance matrix. Then the clustering threshold can be chosen as appropriate.

Regarding the routing graph, to create interconnect routes, a pathfinding approach on a graph is used, in some embodiments. This involves creating a graph representing the free space of the routing problem. This is referred to herein as the “routing graph.” Some embodiments employ a simple grid approach. To construct the graph, a grid of points is laid over the environment. Any points which are on the interior of the environment geometry are removed. The remaining points then become vertices in the routing graph, retaining their point information. Edges are added between adjacent points in the grid with cost equal to the point-to-point distance. Any edges intersecting environment geometry are removed. Lastly, special vertices are added and locally connected to represent the port locations of each of the interconnects.

An important consideration for constructing the graph is the number of vertices. There is a tradeoff between the accuracy and quality of the produced interconnect paths and the computation time. With a larger graph comes longer pathfinding times, so a denser graph will result in slower computation. The density of vertices also affects pathfinding quality in terms of availability of paths and path quality. This can be thought of in terms of minimum cut. For example, if there are two regions of the graph with many ports that must be connected, then, intuitively, the maximum number of possible connections will be restricted by the minimum cut between the regions. Therefore, having a denser graph will increase this maximum number of possible connections, which may be relevant in some scenarios.

As part of the heuristic for generating diversity in the route sets, the vertices of the routing graph are clustered into regions. The primary purpose of this clustering is to create an abstract graph with significantly reduced size from the routing graph which can be used to quickly compute the k-point centrality metric. Using a reduced graph is sometimes necessary due to the expense of computing the k-point centrality.

Depending on the embodiment, either of two clustering methods is applied, both of which accept the number of clusters n as input: Voronoi clustering and spectral clustering. Voronoi clustering has the advantage of simplicity, and it has proven to be effective in practice. The Voronoi decomposition is computed by first choosing n vertices of the routing graph at random to be the centers of the clusters. Each vertex of the graph is then assigned to the cluster to which it is closest using edge cost to determine distance.

The spectral clustering of a graph is computed by using the eigenvectors of the Laplacian of the graph's adjacency matrix as feature vectors in a standard clustering method, such as k-means. Spectral clustering is closely related to minimum graph cuts and is commonly used to find strongly connected regions in a graph. In some embodiments, the Scikit Learn implementation of this algorithm is used.

To create the abstract graph from the routing graph, first the vertices of the routing graph are clustered into n clusters using either Voronoi clustering or spectral clustering. Herein, these clusters are sometimes referred to as “regions.” A vertex is created in the abstract graph for each region. Edges are added between two regions if any vertex of one region is adjacent to a vertex of the other region. The edge cost is the center-to-center distance between the two regions in the abstract graph. The region center is the randomly chosen center in the case of Voronoi clustering, or it is computed using closeness centrality on the region vertices, if spectral clustering is used. Using a fixed number of clusters n allows for easy control of computing the steering heuristic but has the downside of requiring an additional user-provided parameter.

The region decomposition is used to create the region graph. The region graph represents a high-level connectivity of the routing graph and is useful to reduce computation load as the number of vertices in this graph is equal to the number of regions in the decomposition. For each cluster in the region decomposition, the center of the region is computed, and this vertex is added to the region graph. If there are vertices in the routing graph that belong to different regions and are neighbors, an edge connects the associated vertices in the region graph. The cost of this edge is computed as the graph distance in the routing graph between the corresponding region centers. Two mappings are maintained: RegionToRouting, which maps each vertex in the region graph to the associated vertices in the routing graph, and RoutingToRegion, which maps each vertex in the routing graph to the associated vertex in the region graph.

Regarding single-harness routing, a harness is composed of several interconnects that are intended to be bundled, and each interconnect connects two ports specific to that interconnect. In some embodiments, to route the interconnects inside the harness, a two-tiered hierarchical approach is used. Ports are connected locally into a network, and then each local network is connected globally using a Steiner tree. To achieve a variety of results, the global connection can be steered to visit a heuristically selected random region. Routing is done using the routing graph to find valid paths through free space.

Before the local networks are generated, the ports are first clustered. In some embodiments, Affinity Propagation using Euclidean distance between the ports is used for its ability to infer the number of clusters without requiring parameters, though any clustering algorithm could be used. Once the ports are clustered, a center vertex is chosen from the routing graph by finding the vertex closest to the average of the port locations. The ports in the cluster are connected to the center point using the shortest path through the routing graph.

The goal of the global network is to connect the local networks efficiently but with useful randomness. To achieve this, the region graph is first computed from the routing graph. Then the RoutingToRegion mapping is used to map the local network centers to the corresponding vertices of the region map. The k-point centrality is computed on the region graph using the mapped vertices as the k-points. This assigns a score to every vertex of the region graph. The normalized score is then used to create a sampling distribution that can be used to sample regions that are likely to be central to the local network centers. To produce the global routing, a region is sampled from the distribution. The RegionToRouting mapping can be used to find the set of vertices in the routing graph corresponding to the sampled region. Algorithm 3 above is then used to find a Steiner tree in the routing graph connecting each local network center and at least visiting the sampled region by creating a single element set for each local network center and combining that with the region set. Because the global network routing is randomized, by repeatedly finding different global routings, different harness designs can be generated.

Regarding multiple-harness routing, to route multiple harnesses without collision between harnesses, prioritized planning is used, in some embodiments. In those embodiments, each harness is routed in order according to its priority. Harnesses routed later are routed around already-routed harnesses. In some embodiments, a fixed priority determined by an engineer is applied. In other embodiments, a random or heuristic priority based on port distance is applied.

FIGS. 3A-3C illustrate techniques applied in automatically generating alternative route sets, in accordance with an illustrative embodiment of the invention. FIGS. 3A-3C illustrate some of the concepts discussed above relating to block 140, generating the alternative route sets, in process flow 100 (refer to FIG. 1).

FIG. 3A is a simplified two-dimensional representation of an air volume 210 of a target system 200 that has been decomposed into regions 320. Also shown are connection points 230 and components 310 of the target system.

FIG. 3B illustrates the identification of high-density regions 340 and low-density regions 350 of route paths 330. This highlighting of high-density regions supports forming a priority map for waypoint placement, where placing waypoints in the high-priority regions (340) creates more self-similar designs, and placing waypoints in low-priority regions (350) tends to diversify the generated design. This can be used to control the complexity of a generated route set. FIG. 3C illustrates one example of placing waypoints 360.

Returning next to the topic of automatically clustering the alternative route sets into groups (refer to block 150 in FIG. 1), FIGS. 4A-4C illustrate single-factor similarity metrics, in accordance with an illustrative embodiment of the invention.

FIG. 4A illustrates a distance metric 410 that measures the distance corresponding to moving (editing) one route path 330a to coincide with another route path 330b. In some embodiments, this metric is computed using the technique of dynamic time warping (DTW).

FIG. 4B illustrates an interference metric 420 that accounts for the complications resulting from components 310 being located between the two route paths 330, route path 330a and route path 330b. In this example, moving two dots that are part of route path 330a to route path 330b results in those two dots passing through (intersecting with) the component 310. Thus, the interference can be measured as “2” (two intersections with a component 310).

FIG. 4C illustrates a composition metric 430 that accounts for differences in the bundling of wires in a harness. More specifically, the metric measures how much change (difference) exists between two different harnessing configurations. In this simplified example, the composition metric 430 measures the change between Option A and Option B, involving two different colors of wire (blue wire 432 and red wire 434). In Option A, the bundled portion (blue plus red) accounts for 60% of the route path 330, the blue portion for 20%, and the red portion for 20%. In Option B, the bundled portion accounts for 20%, the blue portion for 40%, and the red portion for 40%. The composition metric, in this case, yields 80% change between the two options. This powerful technique can be applied to harnesses including hundreds of wires, where manually identifying the composition of the bundles would be challenging.

In some embodiments, the three single-factor similarity metrics above are combined into an overall multi-factor similarity metric as follows:

$$S = {w}_{1} \cdot D + {w}_{2} \cdot I + {w}_{3} \cdot C ,$$

where S is the multi-factor similarity metric, D is the distance single-factor similarity metric, I is the interference single-factor similarity metric, C is the composition single-factor similarity metric, and the wᵢ are weights applied to the respective three single-factor similarity metrics. The weights wᵢ can be adjusted to change the emergence of designs (route sets). The route sets are then clustered, based at least in part, on the multi-factor similarity metric to identify unique, varied sets of solutions.

FIG. 5 illustrates examples of the application of three single-factor similarity metrics to alternative route sets 510, in accordance with an illustrative embodiment of the invention. In the example of FIG. 5, route sets 510b-e are individually compared with a reference route set 510a using the three single-factor similarity metrics discussed above in connection with FIGS. 4A-4C. In FIG. 5, the value of each single-factor similarity metric relative to the reference route set 510a is indicated below each of the alternative route sets 510b-e.

FIG. 6 illustrates examples of employing randomness in generating alternative route sets 510 to increase variety among the alternative route sets 510, in accordance with an illustrative embodiment of the invention. FIG. 6 depicts six different route sets 510f-k in which variations in the routing of electrical wires have been produced, in part, through the application of randomness.

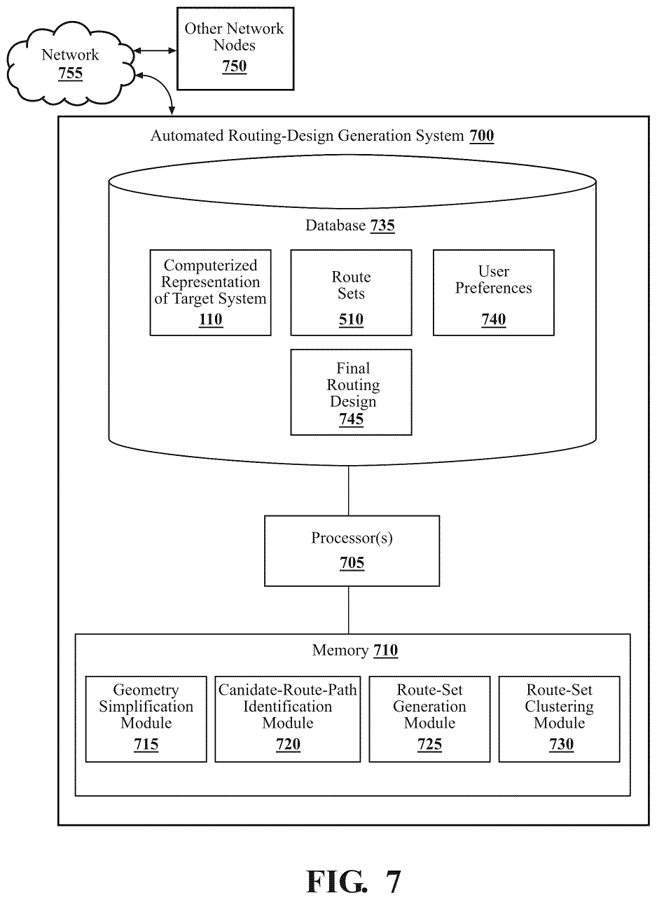

FIG. 7 is a block diagram of an automated routing-design generation system 700, in accordance with an illustrative embodiment of the invention. For brevity, the automated routing-design generation system 700 is often referred to below as simply the “system 700.” As discussed above, the system 700 is a system that can automatically generate routing designs for routing one or more of electrical wires, optical cables, pipes, and hoses between a set of origination connection points 230 and a set of terminal connection points 230 in a target system 200. In FIG. 7, system 700 includes one or more processors 705 with which a memory 710 is communicably coupled. Memory 710 stores a geometry simplification module 715, a candidate-route-path identification module 720, a route-set generation module 725, and a route-set clustering module 730. The memory 710 is a random-access memory (RAM), read-only memory (ROM), a hard-disk drive, a flash memory, or other suitable non-transitory memory for storing the modules 715, 720, 725, and 730. The modules 715, 720, 725, and 730 are, for example, machine-readable instructions that, when executed by the one or more processors 705, cause the one or more processors 705 to perform the various functions disclosed herein.

As shown in FIG. 7, system 700 can store various kinds of data in a database 735. For example, system 700 can store input computerized representations 110, generated alternative route sets 510, user preferences 740, and final routing designs 745. User preferences 740 include a variety of different settings and options a user can use to control the operation of the system 700. For example, without limitation, settings such as the density of control points in the routing mesh, design complexity, harness settings, branch settings, number of routing designs to generate, and settings for the single-factor similarity metrics (distance, interference, and composition) can be stored in user preferences 740. Final routing designs 745 include, for a given target system 200, a final routing design selected from among the clustered groups of alternative route sets 510 or from among the select route sets 510 previously chosen from the groups of route sets 510 (e.g., one from each group) prior to final down-selection.

As shown in FIG. 7, system 700 can communicate with other network nodes 750 (e.g., cloud servers) via a network 755. In some embodiments, network 755 includes the Internet. In communicating with other network nodes 750, system 700 uses communication technologies such as high-speed Ethernet and fiber-optic connections.

Geometry simplification module 715 generally includes machine-readable instructions that, when executed by the one or more processors 705, cause the one or more processors 705 to simplify the geometry of a computerized representation 110 of a target system 200 in which one or more of electrical wires, optical cables, pipes, and hoses are to be routed from a first set of connection points 230 to a second set of connection points 230. The designation “first” and “second,” in this context, is arbitrary. Either set of connection points (the “first” or the “second”) can be a set of origination connection points 230, and the other set of connections points 230 can be a set of terminal connection points 230 in the target system 200. As discussed above, computerized representation 110 can be the product of a CAE platform such as CATIA. In some embodiments, computerized representation 110 includes STL files exported from such a CAE tool and associated metadata such as connection information, design constraints, etc. Such metadata can be stored in, for example, one or more spreadsheets. In these embodiments of an automated routing-design generation system 700, the system imports the STL files and associated metadata prior to simplifying the geometry of the computerized representation 110.

As also discussed above, the various embodiments of an automated routing-design generation system 700 described herein employ numerical methods. CAE representations of a target system such as STL files contain many tessellations that make up the digital rendering. In that form, the calculations involved in generating alternative route sets 510 becomes burdensome. Consequently, system 700 simplifies the geometry of the computerized representation 110 by reducing the number of tessellations that represent a given surface of the target system 200. This speeds up the calculations performed by the system 700. In some embodiments, system 700 simplifies the geometry of computerized representation 110 automatically.

In conjunction with simplifying the geometry of computerized representation 110, system 700 also reviews the connections for the target system 200. This involves analyzing and verifying which origination connection points 230 are to be connected with which terminal connection points 230 in the target system 200.

Candidate-route-path identification module 720 generally includes machine-readable instructions that, when executed by the one or more processors 705, cause the one or more processors 705 to identify automatically candidate route paths 330 between the first and second sets of connection points 230. As discussed above, in some embodiments, this involves defining many discrete points of a routing mesh in the 3D air volume 210 of the target system 200 between the components 310 of the target system 200. The system 700 then determines the feasible (physically possible) route paths 330 in the routing mesh. In some embodiments, each edge (line connecting two mesh points) is assigned a weight based on its length. If a route path lies too close to a sensitive component (e.g., a very hot component), a penalty is assigned to that route, requiring that more expensive wire (e.g., better-insulated wire) be used for that route path. As those skilled in the art will recognize, this presents a tradeoff between adding more length to the wire to avoid getting too close to a sensitive component and accepting the penalty and using the more expensive wire with better insulation to pass more closely to the sensitive component.

Route-set generation module 725 generally includes machine-readable instructions that, when executed by the one or more processors 705, cause the one or more processors 705 to generate automatically, based on the candidate route paths 330, alternative route sets 510 in accordance with one or more constraints. As discussed above, the number of route sets 510 the system generates varies, depending on the embodiment and user settings/preferences. For example, in one embodiment, the system might generate tens of route sets; in another embodiment, hundreds. Additional conceptual and mathematical details regarding the automatic generation of the alternative route sets 510 are presented above, and FIGS. 3A-3C illustrate some of those concepts.

As also discussed above, in connection with automatically generating the alternative route sets 510, a user of the system 700 can adjust certain route-dependent constraints. For example, the system can include a user interface element (e.g., a virtual slider) that permits the user to select the “complexity” of the generated route sets 510. At one extreme, the system produces route sets 510 including the simplest possible route paths 330. At the other extreme, the system produces route sets 510 including route paths 330 that are elaborate and roundabout. A user can adjust the complexity to be somewhere between those two extremes. Choosing a setting somewhere between the two extremes helps to ensure that a diversity of designs (alternative route sets 510) is produced. The “harness settings” constraint limits the maximum distance between connectors that lead to a single branch point. Though this particular constraint applies to electrical wires or optical cables, there are analogous considerations for pipes, hoses, etc. The “branch settings” constraint (1) limits the maximum number of wires that can diverge at a given branch point and (2) limits the minimum length of wire from connector to branch point for assembly considerations.

As also discussed above, at the stage of generating the alternative route sets 510, the technique of randomly assigning some of the wires to harnesses helps to increase the variety of the routing designs the system 700 produces. This is discussed above in connection with FIG. 6.

Route-set clustering module 730 generally includes machine-readable instructions that, when executed by the one or more processors 705, cause the one or more processors 705 to cluster automatically the alternative route sets 510 into groups based, at least in part, on a multi-factor similarity metric that is a sum of weighted single-factor distance (410), interference (420), and composition similarity (430) metrics. This aspect of system 700, including the multi-factor and single-factor similarity metrics (410, 420, and 430), is discussed in greater detail above in connection with FIGS. 4A-C and 5.

As discussed above, in some embodiments, the system 700 automatically selects one representative route set 510 from each group (cluster) of alternative route sets 510 prior to final selection of a routing design (745). Regardless of whether the alternative route sets 510 are first reduced in number in that fashion, a particular route set (745) is ultimately selected from among the alternative route sets 510, and that particular route set (745) is implemented (built out) in the target system 200. In some embodiments, one or more design engineers make the final selection of the particular route set (745) to be implemented in the target system 200.

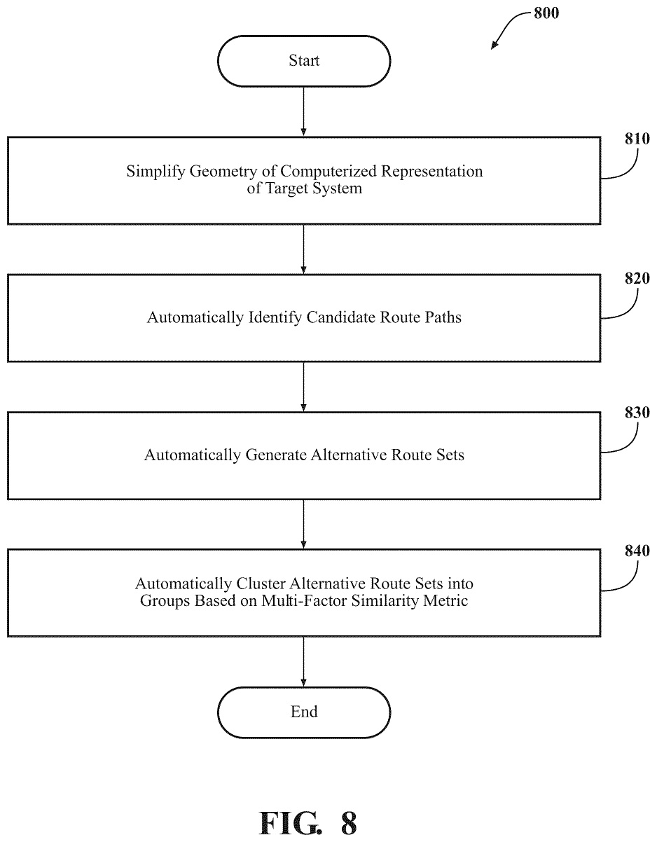

FIG. 8 is a flowchart of a method 800 of automatically generating routing designs, in accordance with an illustrative embodiment of the invention. Method 800 will be discussed from the perspective of the automated routing-design generation system 700 in FIG. 7. While method 800 is discussed in combination with the system 700, it should be appreciated that method 800 is not limited to being implemented within the system 700, but the system 700 is instead one example of a system that may implement method 800.

At block 810, geometry simplification module 715 simplifies the geometry of a computerized representation 110 of a target system 200 in which one or more of electrical wires, optical cables, pipes, and hoses are to be routed from a first set of connection points 230 to a second set of connection points 230. As discussed above, the designation “first” and “second,” in this context, is arbitrary. Either set of connection points (the “first” or the “second”) can be a set of origination connection points 230, and the other set of connections points 230 can be a set of terminal connection points 230 in the target system 200. As also discussed above, computerized representation 110 can be the product of a CAE platform such as CATIA. In some embodiments, computerized representation 110 includes STL files exported from such a CAE tool and associated metadata such as connection information, design constraints, etc. Such metadata can be stored in, for example, one or more spreadsheets. In these embodiments of an automated routing-design generation system 700, the system imports the STL files and associated metadata prior to simplifying the geometry of the computerized representation 110.

As also discussed above, the various embodiments of an automated routing-design generation system 700 described herein employ numerical methods. CAE representations of a target system such as STL files contain many tessellations that make up the digital rendering. In that form, the calculations involved in generating alternative route sets 510 becomes burdensome. Consequently, system 700 simplifies the geometry of the computerized representation 110 by reducing the number of tessellations that represent a given surface of the target system 200. This speeds up the calculations performed by the system 700. In some embodiments, system 700 simplifies the geometry of computerized representation 110 automatically.

In conjunction with simplifying the geometry of computerized representation 110, system 700 (e.g., geometry simplification module 715) also reviews the connections for the target system 200. This involves analyzing and verifying which origination connection points 230 are to be connected with which terminal connection points 230 in the target system 200.

At block 820, candidate-route-path identification module 720 automatically identifies candidate route paths 330 between the first and second sets of connection points 230. As discussed above, in some embodiments, this involves defining many discrete points of a routing mesh in the 3D air volume 210 of the target system 200 between the components 310 of the target system 200. The system 700 then determines the feasible (physically possible) route paths 330 in the routing mesh. In some embodiments, each edge (line connecting two mesh points) is assigned a weight based on its length. If a route path 330 lies too close to a sensitive component (e.g., a very hot component), a penalty is assigned to that route path 330, requiring that more expensive wire (e.g., better-insulated wire) be used for that route path 330. As those skilled in the art will recognize, this presents a tradeoff between adding more length to the wire to avoid getting too close to a sensitive component and accepting the penalty and using the more expensive wire with better insulation to pass more closely to the sensitive component.

At block 830, route-set generation module 725 automatically generates, based on the candidate route paths 330, alternative route sets 510 in accordance with one or more constraints. As discussed above, the number of alternative route sets 510 the system generates varies, depending on the embodiment and user settings/preferences. For example, in one embodiment, the system might generate tens of route sets; in another embodiment, hundreds. Additional conceptual and mathematical details regarding the automatic generation of the alternative route sets 510 are presented above, and FIGS. 3A-3C illustrate some of those concepts.

As also discussed above, in connection with automatically generating the alternative route sets 510, a user of the system 700 can adjust certain route-dependent constraints. For example, the system can include a user interface element (e.g., a virtual slider) that permits the user to select the “complexity” of the generated route sets 510. At one extreme, the system produces route sets including the simplest possible route paths. At the other extreme, the system produces route sets including route paths that are elaborate and roundabout. A user can adjust the complexity to be somewhere between those two extremes. Choosing a setting somewhere between the two extremes helps to ensure that a diversity of designs (alternative route sets 510) is produced. The “harness settings” constraint limits the maximum distance between connectors that lead to a single branch point. Though this particular constraint applies to electrical wires or optical cables, there are analogous considerations for pipes, hoses, etc. The “branch settings” constraint (1) limits the maximum number of wires that can diverge at a given branch point and (2) limits the minimum length of wire from connector to branch point for assembly considerations.

As also discussed above, at the stage of generating the alternative route sets 510, the technique of randomly assigning some of the wires to harnesses helps to increase the variety of the routing designs the system 700 produces. This is discussed above in connection with FIG. 6.

At block 840, route-set clustering module 730 automatically clusters the alternative route sets 510 into groups based, at least in part, on a multi-factor similarity metric that is a sum of weighted single-factor distance (410), interference (420), and composition (430) similarity metrics. This aspect of system 700, including the multi-factor and single-factor similarity metrics (410, 420, and 430), is discussed in greater detail above in connection with FIGS. 4A-C and 5.

As discussed above, in some embodiments, the system 700 automatically selects one representative route set 510 from each group (cluster) of route sets 510 prior to final selection of a routing design (final routing design 745). Regardless of whether the alternative route sets 510 are first reduced in number in that fashion, a particular route set (745) is ultimately selected from among the alternative route sets 510, and that particular route set 745 is implemented (built out) in the target system 200. In some embodiments, one or more human design engineers make the final selection of the particular route set 745 to be implemented in the target system 200.

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-6, but the embodiments are not limited to the illustrated structure or application.

The components described above can be realized in hardware or a combination of hardware and software and can be realized in a centralized fashion in one processing system or in a distributed fashion where different elements are spread across several interconnected processing systems. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain or store a program for use by or in connection with an instruction execution system, apparatus, or device.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Generally, “module,” as used herein, includes routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e. open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g. AB, AC, BC or ABC).

As used herein, “cause” or “causing” means to make, command, instruct, and/or enable an event or action to occur or at least be in a state where such event or action may occur, either in a direct or indirect manner.

Aspects herein can be embodied in other forms without departing from the spirit or essential attributes thereof. Accordingly, reference should be made to the following claims rather than to the foregoing specification, as indicating the scope hereof.

What is claimed is:

1. A system, comprising:
a processor; and
a memory storing machine-readable instructions that, when executed by the processor, cause the processor to:
simplify the geometry of a computerized representation of a target system in which one or more of electrical wires, optical cables, pipes, and hoses are to be routed from a first set of connection points to a second set of connection points;
identify automatically candidate route paths between the first and second sets of connection points;
generate automatically, based on the candidate route paths, alternative route sets in accordance with one or more constraints; and
cluster automatically the alternative route sets into groups based, at least in part, on a multi-factor similarity metric that is a sum of weighted single-factor distance, interference, and composition similarity metrics;
wherein a particular route set selected from among the alternative route sets in the groups is implemented in the target system.

2. The system of claim 1, wherein the constraints include a design-complexity setting, harness settings, and branch settings.

3. The system of claim 1, wherein the machine-readable instructions to generate automatically the alternative route sets include instructions that, when executed by the processor, cause the processor to:
decompose an air volume between components of the target system into a plurality of regions and compute a heuristic that yields a probability distribution over the plurality of regions;
identify high-density regions among the plurality of regions; and
place waypoints in prioritized regions among the plurality of regions to control complexity of the alternative route sets.

4. The system of claim 3, wherein the machine-readable instructions to decompose the air volume between the components of the target system into the plurality of regions and to compute the heuristic that yields the probability distribution over the plurality of regions include instructions that, when executed by the processor, cause the processor to apply one of Voronoi clustering and spectral clustering.

5. The system of claim 3, wherein the heuristic is a steered two-point centrality heuristic.

6. The system of claim 1, wherein the machine-readable instructions to generate automatically the alternative route sets include instructions that, when executed by the processor, cause the processor to randomly assign electrical wires to a harness to increase variety in the alternative route sets.

7. The system of claim 1, wherein the target system is one of a vehicle, a fuel-cell system of a vehicle, a hydraulic system of a vehicle, a power plant, an oil refinery, an aircraft engine, and a computing system.

8. The system of claim 1, wherein the machine-readable instructions include further instructions that, when executed by the processor, cause the processor to select automatically, from each group, one route set from among the alternative route sets in that group to produce a final group of candidate route sets, wherein the particular route set is selected from among the final group of candidate route sets.

9. A non-transitory computer-readable medium storing instructions that, when executed by a processor, cause the processor to:
simplify the geometry of a computerized representation of a target system in which one or more of electrical wires, optical cables, pipes, and hoses are to be routed from a first set of connection points to a second set of connection points;
identify automatically candidate route paths between the first and second sets of connection points;
generate automatically, based on the candidate route paths, alternative route sets in accordance with one or more constraints; and
cluster automatically the alternative route sets into groups based, at least in part, on a multi-factor similarity metric that is a sum of weighted single-factor distance, interference, and composition similarity metrics;
wherein a particular route set selected from among the alternative route sets in the groups is implemented in the target system.

10. The non-transitory computer-readable medium of claim 9, wherein the instructions to generate automatically the alternative route sets include instructions that, when executed by the processor, cause the processor to:
decompose an air volume between components of the target system into a plurality of regions and compute a heuristic that yields a probability distribution over the plurality of regions;
identify high-density regions among the plurality of regions; and
place waypoints in prioritized regions among the plurality of regions to control complexity of the alternative route sets.

11. The non-transitory computer-readable medium of claim 10, wherein the instructions to decompose the air volume between the components of the target system into the plurality of regions and to compute the heuristic that yields the probability distribution over the plurality of regions include instructions that, when executed by the processor, cause the processor to apply one of Voronoi clustering and spectral clustering.

12. The non-transitory computer-readable medium of claim 10, wherein the heuristic is a steered two-point centrality heuristic.

13. The non-transitory computer-readable medium of claim 9, wherein the instructions to generate automatically the alternative route sets include instructions that, when executed by the processor, cause the processor to randomly assign electrical wires to a harness to increase variety in the alternative route sets.

14. A method, comprising:
simplifying the geometry of a computerized representation of a target system in which one or more of electrical wires, optical cables, pipes, and hoses are to be routed from a first set of connection points to a second set of connection points;
identifying automatically candidate route paths between the first and second sets of connection points;
generating automatically, based on the candidate route paths, alternative route sets in accordance with one or more constraints; and
clustering automatically the alternative route sets into groups based, at least in part, on a multi-factor similarity metric that is a sum of weighted single-factor distance, interference, and composition similarity metrics;
wherein a particular route set selected from among the alternative route sets in the groups is implemented in the target system.

15. The method of claim 14, wherein the constraints include a design-complexity setting, harness settings, and branch settings.

16. The method of claim 14, wherein the generating automatically the alternative route sets includes:
decomposing an air volume between components of the target system into a plurality of regions and computing a heuristic that yields a probability distribution over the plurality of regions;
identifying high-density regions among the plurality of regions; and
placing waypoints in prioritized regions among the plurality of regions to control complexity of the alternative route sets.

17. The method of claim 16, wherein the decomposing includes one of Voronoi clustering and spectral clustering.

18. The method of claim 16, wherein the heuristic is a steered two-point centrality heuristic.

19. The method of claim 14, wherein the generating automatically the alternative route sets includes randomly assigning electrical wires to a harness to increase variety in the alternative route sets.

20. The method of claim 14, further comprising selecting automatically, from each group, one route set from among the alternative route sets in that group to produce a final group of candidate route sets, wherein the particular route set is selected from among the final group of candidate route sets.
